(19) United States
(12) Patent Application Publication
(10) Pub. No.: US 2026/0180286 A1
(43) Pub. Date: Jun. 25, 2026

(54) DEVICE AND METHOD FOR GENERATING COHERENT TERAHERTZ RADIATION

(71) Applicant: COMMISSARIAT A L'ENERGIE ATOMIQUE ET AUX ENERGIES ALTERNATIVES, Paris (FR)

(72) Inventors: Alexandre GOEURY, Le Barp Cedex (FR); Jacques GARDELLE, Le Barp Cedex (FR); Bruno CASSANY, Le Barp Cedex (FR)

(73) Assignee: COMMISSARIAT A L'ENERGIE ATOMIQUE ET AUX ENERGIES ALTERNATIVES, Paris (FR)

(21) Appl. No.: 18/995,277

(22) PCT Filed: Jul. 13, 2023
(86) PCT No.: PCT/FR2023/051089

§ 371 Date: Jan. 16, 2025

(30) Foreign Application Priority Data
Jul. 22, 2022 (FR) 2207571

(51) Int. Cl. H01S 5/14; G11B 7/09; H01J 5/22; H01J 37/153; H01J 37/28; H01J 37/317; H01S 3/08; H01S 3/09

(52) U.S. Cl. CPC H01S 5/141; G11B 7/0903; H01J 5/22; H01J 37/153; H01J 37/28; H01J 37/3174; H01S 3/08009; H01S 3/0903

(57) ABSTRACT

A method and a device for producing coherent Smith-Purcell electromagnetic radiation. The device includes an electrically conductive diffraction grating laterally defined by two electrically conductive outer side walls; a source for generating an electron beam above the diffraction grating. The electron beam is configured to interact with the diffraction grating so as to produce coherent Smith-Purcell electromagnetic radiation directed upstream of the diffraction grating in a predetermined direction. The device further includes a mirror configured to collect all of the electromagnetic radiation and redirect it parallel to the diffraction grating to an exit downstream of the diffraction grating.

### TECHNICAL FIELD

The present invention relates to the field of coherent electromagnetic sources in the THz terahertz range, in particular generators of coherent Smith-Purcell radiation.

### PRIOR ART

At present, there are two technologies for coherent electromagnetic sources in the THz range.

A first technology relates to equipment generating electromagnetic radiation at high frequency by stimulated resonance of free electrons moving through a powerful magnetic field. This equipment can in general deliver powers greater than one watt under a frequency of 1 THz but is relatively costly and not very compact. The gyrotron is a piece of equipment of this type of technology that requires strong very magnetic fields, produced by superconductor magnets inserted into cryostats. This very costly and voluminous piece of equipment can deliver a very high power of approximately one kW continuously but at a single frequency.

A second technology relates to the relatively compact quantum cascade lasers (QCLs) that can generate a frequency of 1 THz but with an emitted power that does not exceed one mW. Moreover, these laser sources are not tunable that is to say that it is necessary to change the laser source to change frequency.

In the prior art, there are relatively compact devices that can deliver high-power THz radiation. This type of device uses the properties in three dimensions of a diffraction grating to generate coherent Smith-Purcell radiation with high efficiency. Such devices or methods are described in the article by J. T. Donohue and J. Gardelle, “Simulation of a Smith-Purcell free-electron laser with sidewalls: Copious emission at the fundamental frequency”, AppliedPhysics Letters 99 (2011), 161112-1, as well as in the French patents FR 3004294 and FR 2980923.

The goal of the present invention is to propose a device and a method for generating coherent Smith-Purcell radiation, allowing to improve the devices described in the patents cited above by even further simplifying the implementation, by reducing the costs and by optimizing the compactness.

Another goal of the present invention is to propose a tunable device for producing coherent Smith-Purcell radiation, allowing to vary the radiation frequency.

### DISCLOSURE OF THE INVENTION

This goal is reached with a device for producing coherent Smith-Purcell electromagnetic radiation comprising:
an electrically conductive diffraction grating, defined in terms of width by two electrically conductive outer side walls;
a source for emitting an electron beam and propagating it above the diffraction grating, the electron beam being configured to interact with the diffraction grating so as to produce coherent Smith-Purcell electromagnetic radiation directed upstream of the diffraction grating in a predetermined direction; and
a mirror configured to collect most of the electromagnetic radiation in order to redirect it parallel to the diffraction grating to an exit downstream of the diffraction grating.

Thus, the device according to the invention is compact, economical and easy to implement while generating high-power coherent electromagnetic radiation in the THz range.

Advantageously, the mirror includes a reflective surface, the geometric shape of which is determined on the basis of the radiation pattern of the diffraction grating while taking into account the emission lobes. The shape of the mirror is thus optimized to send the power emitted back to the outlet of the device.

Advantageously, the characteristics of the electron beam include:
a speed of the electrons sufficiently low so that in a dispersion diagram, in which the frequency is expressed according to the wave number, a straight line representing the frequency of the electron beam according to its wave number and a curve representing, in the first Brillouin zone, the dispersion relation in three dimensions corresponding to the fundamental mode of the diffraction grating intersect at a point located outside of an isosceles triangle, the base of which is the same as the axis of the abscissae of the dispersion diagram and one side of which is a line segment having a slope of c/2πpassing through the origin of said diagram, where c is the speed of light in a vacuum; and
a current density sufficiently high to efficiently excite the fundamental mode of the diffraction grating.

A strongly directional electromagnetic radiation coming directly from the fundamental mode of interaction between the electron beam and the diffraction grating can thus be obtained.

Advantageously, the device includes:
a tube, the axis of which is parallel to the propagation of the electron beam, said tube being connected to the source at one end and ends in an exit port at the other end, and
a support disposed inside the tube between the source and the exit port onto which the diffraction grating and the mirror are fastened in a removable manner.

Thus, the mirror and/or the grating can be replaced by another mirror and/or grating on the support with the goal of modifying the emission frequency of the electromagnetic radiation according to the parameters desired by the operator.

Advantageously, the support includes a first part having a circular surface perpendicular to the axis of the tube and provided with a circular orifice to let the electron beam pass through and a second part having a rectangular surface parallel to the axis of the tube, the mirror being fastened onto the circular part of the support while the diffraction grating is fastened onto the rectangular part of the support.

This facilitates the extraction of the support to change the mirror and/or the grating.

Advantageously, the device includes an element for stopping the beam fastened onto the rectangular part of the support downstream of the diffraction grating, said element for stopping the beam being intended to absorb the beam downstream of the grating.

This allows to stop the beam as soon as the electrons have stopped interacting with the grating.

Advantageously, the element for stopping the beam has a geometric shape configured to distribute the current density of the electron beam over the largest possible surface area while letting the electromagnetic radiation pass through the exit port.

Advantageously, the tube provided with the source and the exit port forms a vacuum chamber inside of which the pressure is approximately 10⁻⁸ mbar to 10⁻⁷ mbar.

Advantageously, the device includes elements for magnetic focusing and guiding configured to focus, guide and maintain the electron beam in a zone located above the diffraction grating.

The invention also relates to a method for producing coherent Smith-Purcell electromagnetic radiation in which:
an electrically conductive diffraction grating, laterally defined by two electrically conductive outer side walls, is used;
an electron beam is propagated above the diffraction grating, the electron beam being configured to interact with the diffraction grating so as to produce coherent Smith-Purcell electromagnetic radiation directed upstream of the diffraction grating in a predetermined direction; and
a mirror configured to collect all of the electromagnetic radiation and to redirect it parallel to the diffraction grating to an exit downstream of the diffraction grating is used.

### BRIEF DESCRIPTION OF THE DRAWINGS

The present invention will be better understood upon reading the description of exemplary embodiments given for purely informational and in no way limiting purposes, while referring to the appended drawings among which:

FIG. 1A schematically shows a device for generating electromagnetic radiation, according to an embodiment of the invention;

FIG. 1B is a schematic perspective view of a diffraction grating usable in the device of FIG. 1A;

FIG. 2 illustrates an example of a dispersion diagram of the diffraction grating, according to an embodiment of the invention;

FIG. 3 schematically shows a propagation module of the device illustrating the interchangeability of its removable elements, according to an embodiment of the invention; and

FIG. 4A

FIG. 4B

FIG. 4C

FIG. 4D illustrate the dimensioning of the mirror according to the radiation pattern, according to an embodiment of the invention.

### DETAILED DISCLOSURE OF SPECIFIC EMBODIMENTS

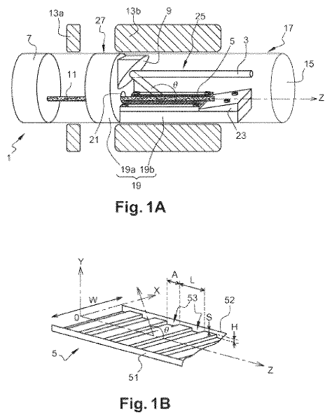

FIG. 1A schematically shows a device for generating electromagnetic radiation, according to an embodiment of the invention. Moreover, FIG. 1B is a schematic perspective view of a diffraction grating usable in the device of FIG. 1A.

This device 1 is intended to produce coherent Smith-Purcell radiation 3 with a high efficiency. It includes a diffraction grating 5, a source of electrons 7 and a mirror 9.

The diffraction grating 5 is electrically conductive and preferably non-magnetic. It is laterally defined by two walls 51 and 52 also electrically conductive and preferably non-magnetic.

The source 7 is an electron gun (for example, a thermionic gun) intended to produce an electron beam 11 that propagates along an axis Z, above the diffraction grating 5, between the two walls 51 and 52.

The electron beam 11 is configured to interact with the diffraction grating 5 so as to produce coherent Smith-Purcell electromagnetic radiation 3.

The diffraction grating 5 has a series of grooves 53 having a rectangular profile and parallel to each other. This is therefore called a lamellar diffraction grating 5. Other types of profile are also possible, for example triangular or sinusoidal, without going beyond the context of the present invention.

The axis Z, along which the electron beam 11 propagates, is perpendicular to the furrows 53. And moreover, an axis X that is parallel to the furrows 53, and thus perpendicular to the axis Z, as well as an axis Y that is perpendicular to the axes X and Z as visible in FIG. 1B, are defined. The three axes X, Y and Z intersect at a point O thus forming a Cartesian coordinate system.

The width of the diffraction grating 5 (i.e. the distance between its two side walls 51, 52) is noted as W and the height of the side walls 51, 52 as S. The thickness (respectively the depth) of the grooves 53 is noted as A (respectively H). The period of the diffraction grating 5 is noted as L and the number of periods as N.

Preferably, the width W=2L. The period L is chosen according to the operating wavelength of the desired use.

It is recalled that the Smith-Purcell radiation 3 is emitted at an angle θ with respect to the axis Z of propagation of the electron beam, according to the following relationship:

$$\begin{matrix}[ Math 1 ] & \\ λ = ci f = L ( 1 / β - cos θ ) / \vert n \vert & ( 1 )\end{matrix}$$

where λ represents the wavelength of the radiation in a vacuum, f the frequency of this radiation, c the speed of light in a vacuum, β the ratio v/c (v: speed of the electrons) and n the order of diffraction.

The formula (1) suffices to give the order of magnitude before an exact calculation of the modes of the grating in three dimensions. The present invention is indeed based on the theory of the modes in three dimensions of a diffraction grating 5 having a given width W, equipped with side walls 51, 52. In this respect, see the French patents FR 3004294 and FR 2980923.

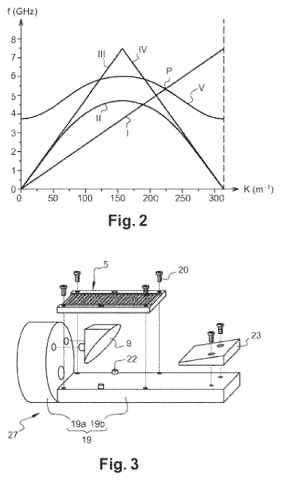

FIG. 2 illustrates an example of a dispersion diagram (f, k) of the diffraction grating, according to an embodiment of the invention.

The dispersion diagram shows the frequency of the radiation f according to the wave number k. This is limited to the first Brillouin zone, having a length 2π/L. The straight line I, the equation of which is f=vk/2π, represents the frequency of the electron beam 11 according to the wave number k, is called the “straight line of the beam”. The curve II represents the dispersion relation of the diffraction grating 5 in two dimensions.

The straight lines III and IV respectively correspond to the “light line-front” having the equation f=ck/2π and to the “light line-rear”.

The straight lines III, IV and the axis of the abscissae (wave number k) define a triangle called “triangle of the light”.

If the point of intersection between the straight line of the beam I and the curve representative of the dispersion relation of the grating 5 is located inside the triangle of light, which is always the case in two dimensions, the device cannot emit in the fundamental mode. The latter is thus an evanescent surface wave in the direction Y. Only the harmonics of the fundamental frequency can thus be emitted with a low efficiency.

The curve V represents, in the first Brillouin zone, the dispersion relation in three dimensions corresponding to the fundamental mode of the diffraction grating 5. The point of intersection P can thus be outside of the triangle of light, and a coherent emission in the fundamental mode is thus allowed since the relation (1) is satisfied.

In the example described, the point P is thus chosen as an operating point of the beam-grating system. In other words, the speed of the electrons (or, which amounts to the same thing, the kinetic energy of the latter) is chosen so that the straight line of the beam I intersects the curve V at the point P.

In general, in the present invention, the speed of the electrons is chosen as sufficiently low so that, in the dispersion diagram (k, f) of the grating-beam assembly, the beam line intersects a part of a branch of the dispersion relation, located in the first Brillouin zone and corresponding to the fundamental mode of the diffraction grating 5, at a point P located outside of the triangle of the light.

According to a specific embodiment of the present invention, table Tab1 gives the values of the frequency in GHz of the operating point P for a circular electron beam 11, the kinetic energy of which is 60 keV, interacting with the fundamental mode of the diffraction grating 5 equipped with its side walls 51, 52, having a period L in mm. According to this example, the diffraction grating 5 has a rectangular profile of the grooves and its dimensions are H=A=L/2 and W=2L.

TABLE 1
operating frequencies for KE = 60 keV. H = A = L/2 and W = 2L.

| L (mm) | f (GHz) |
|---|---|
| 0.3 | 335 |
| 0.2 | 505 |
| 0.15 | 673 |
| 0.1 | 1005 |

Via the side walls 51, 52 located on the sides of the diffraction grating 5, it is possible to extract the fundamental mode of the grating 5. Half of the energy deposited by the electron beam 11 in the diffraction grating 5 is expected in the form of electromagnetic radiation in this fundamental mode. As a reminder, a diffraction grating 5 in two dimensions can only emit Smith-Purcell radiation at the harmonic frequencies of the latter. In any electromagnetic system, the harmonic frequencies always carry less energy than the fundamental frequency.

Moreover, the continuous and circular electron beam 11 is chosen according to the following characteristics:
The current density of the electron beam 11 is sufficiently high to strongly excite the fundamental mode of the diffraction grating 5;
The electrons have an energy of 60 keV at the diffraction grating;
The electron beam 11 is advantageously shaped via a magnetic transport line 13a, 13b, the maximum axial magnetic field of which can reach 1.5 Tesla. This magnetic field allows to maintain the electron beam 11 along the diffraction grating 5 and achieve an electron beam radius of between 20 μm and 50 μm thus allowing to optimize the interaction. The stronger the axial magnetic field near the grating, the smaller the equilibrium radius (without transverse oscillations along the grating) of the beam.

For example, by using the Smith-Purcell relation for a grating having a period L of 0.3 mm and for a kinetic energy of the electrons of 60 keV, it is deduced therefrom that the radiation is expected at an angle of around 138° with respect to the direction of propagation of the electron beam 11. The kinetic energy of the electrons of 60 keV ensures a good compromise in terms of compactness, high gain value and a reasonable electric power of the electron beam 11 to have a significant emitted power.

Thus, according to the present invention, the radiation 3 is directed towards upstream (i.e. the rear) of the diffraction grating 5 (here, the term upstream is defined with respect to the direction of propagation of the electron beam 11) according to a predetermined direction (angle θ).

In turn, the shape of the mirror 9 is calculated to collect most of the electromagnetic radiation 3 and to redirect it parallel to the diffraction grating 5 to an outlet 15 (an exit port) downstream (i.e. in front of) the diffraction grating 5.

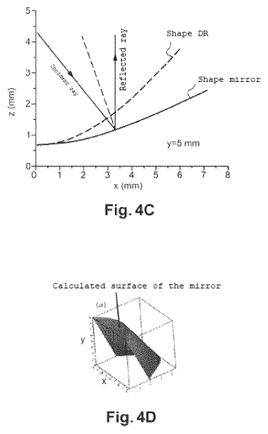

Advantageously, the mirror 9 includes a reflective surface, the geometric shape of which is determined on the basis of the 3D complete radiation pattern “DR” of the diffraction grating 5 defining the various modes emitted by the latter (generating the radiation in the direction θ but also in the azimuth direction φ). The simulation tool used can be a software of the CSTR type. The radiation pattern is described in more detail in relation to FIGS. 4A-4D.

Moreover, the embodiment of FIG. 1A shows that the device 1 includes a tube 17, the axis of revolution of which is parallel to the propagation of the electron beam 11 (i.e. in the direction of the axis Z).

The tube 17 is defined by the source 7 of the electrons at one end and by an exit port 15 at the other end. Thus, the tube 17 provided with the source 7 and the exit port 15 forms a vacuum chamber inside of which the pressure is approximately 10⁻⁸ mbar to 10⁻⁷ mbar (with 10⁵ Pa=1 bar=1000 mbar). Preferably, the cylindrical tube 17 is made of non-magnetic metal.

Moreover, the device 1 includes a support 19, disposed inside the tube 17 between the source 7 and the exit port 15, onto which the diffraction grating 5 and the mirror 9 are fastened (via screws 20 and/or pins 22) in a removable manner on the axis Z. Preferably, the support 19 is non-magnetic. Advantageously, the support 19 resists over 300° C.

According to a specific embodiment of the present invention, the support 19 includes a first part 19a in the plane (X, Y) having a circular surface perpendicular to the axis of the tube 17 (i.e. the axis Z). This first part 19a of the support is provided with a circular orifice 21 to let the electron beam 11 pass through. The mirror 9 is fastened onto this circular part 19a of the support.

The support 19 includes a second part 19b in the plane (X, Z) having a rectangular surface parallel to the axis Z of the tube 17. The diffraction grating 5 is fastened onto this rectangular part 19b of the support so that the electron beam passing through the hole 21 can propagate with raking incidence along the grating 5. The space between the circular part 19a of the support and the exit port 15 forms the propagation chamber 25.

Moreover, the device 1 includes an element 23 for stopping the beam fastened onto the rectangular part 19b of the support 19 located downstream of the diffraction grating 5. The element 23 for stopping the beam is intended to absorb the electron beam 11 downstream of the diffraction grating 5.

Advantageously, the element 23 for stopping the beam has a geometric shape configured to distribute the collection of the electrons over the largest possible surface area in order to minimize the current density of the electron beam 11 on the stopping element, without obstructing the passage of the radiation 3 which can thus pass through the exit port 15. Advantageously, the element 23 for stopping the beam is made of graphite.

The support 19 as well as the mirror 9, the diffraction grating 5, and the stopping element 23 form a THz propagation module 27 disposed in the propagation chamber 25. The THz propagation module 27 according to the present invention is very compact, its length does not exceed several tens of mm being integrated into a tube 17 under vacuum having a diameter that does not exceed 20 mm.

Thus, the mirror 9 and the diffraction grating 5 are interchangeable on the support 19 with the goal of modifying the emission frequency of the electromagnetic radiation 3 according to the parameters desired by the operator.

Advantageously, the device 1 includes elements for focusing 13a and guiding 13b (for example, a magnetic transport line) disposed outside of the tube 17. These elements 13a, 13b are configured to focus, guide and maintain the electron beam 11 in the zone located above the diffraction grating 5.

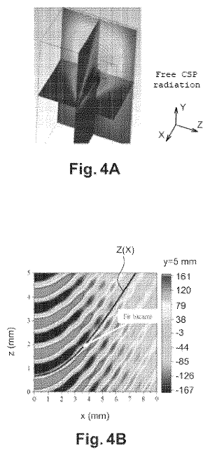

FIG. 3 schematically shows the THz propagation module of the device illustrating the interchangeability of these removable elements, according to an embodiment of the invention.

The implementation of the process for changing the diffraction grating 5 and/or the mirror 9 is relatively simple and fast. The steps allowing to change the emission frequency of the device 1 are the following:
1. Closing an isolation valve (not shown) located between the electron gun 7 and the propagation chamber 25 under vacuum containing the THz propagation module 27. It is noted that the electron gun 7 remains constantly under vacuum;
2. Venting the tube under vacuum and opening the propagation chamber 25 by removing the exit port 15;
3. Extracting the THz propagation module 27 using a self-locking stop pin inserted into the support 19;
4. Disassembling the clamping screws 20 of the grating 5 and/or of the mirror 9;
5. Mounting the new grating 5 and/or the mirror 9;
6. Placing the new THz propagation module 27 in the propagation chamber 25 using the pin;
7. Closing the propagation chamber 25 by putting back the exit port 15;
8. Placing under vacuum (10⁻⁷ mbar-10⁻⁸ mbar) and opening the isolation valve.

It is noted that the mirror 9 is inserted inside the tube 17 under vacuum in a reduced space above the grating 5. As indicated above, with the goal of sending all of the emitted power back to the outlet of the device 1, the mirror 9 is dimensioned on the basis of the complete radiation pattern “DR” of the diffraction grating 5 generating the radiation in the direction θ but also in the direction φ (spherical coordinate).

Indeed, FIGS. 4A-4D illustrate the dimensioning of the mirror according to the radiation pattern, according to an embodiment of the invention.

More particularly, FIG. 4A shows a radiation pattern calculated for a diffraction grating having a period L of 0.3 mm, according to an embodiment of the invention.

The radiation pattern, observable by tracing at various time intervals the values of the axial component of the Poynting vector (emitted power density) in the entire space. After a time t>1ns, the radiation pattern keeps the same shape with only local variations in the intensity of the field. The emission at the Smith-Purcell angle (138° for a grating having a period L of 0.3 mm) is visible in the cutting plane YOZ but a large part of the emission extends in the direction φ.

Secondly, the shape of the mirror 9 is determined by using the principles of geometric optics. It is based on the study of the radiation pattern of the grating alone in space and is obtained using CSTR. Rather than working on the the Poynting vector, it is possible to work with t contours of the component Bx of the magnetic field (along the direction X) which is more suitable for observing the front of the waves coming from the diffraction grating 5. As indicated above, the angle of emission in the plane YOZ is the Smith-Purcell angle of 138°. However, in the planes (X, Z), the angles are a little more complex to estimate.

FIG. 4B shows precisely the radiation in a plane (X, Z) of the pattern of FIG. 4A. This type of pattern allows to determine the angles in the planes (X, Z) for various values of Y.

In particular, FIG. 4B is an example showing the contour Bx in the plane Y=5 mm. By knowing the Z coordinate of the position in which the mirror 9 can be mechanically placed, the contour Z(X) that the mirror must have at this location to intercept the rays coming from the grating and send them back parallel to the axis Z can be made to correspond “fitter”.

FIG. 4C schematically illustrates the building of the surface of the mirror, according to an embodiment of the invention.

The use of a biquadratic polynomial is sufficient to reconstruct the curve of the mirror at any vertical position Y. Knowing the wave-front curve in this plane in the form of a polynomial, it is possible to trace at each point xo of this curve two straight lines corresponding to the normal and the tangent. The normal at xo corresponds to a light ray coming from the diffraction grating 5 that must be sent back to the front parallel to the axis OZ. The tangent at xo is used to determine a point on the new curve Z (XM) that will allow to describe the shape of the mirror 9 in the plane Y considered. Knowing the angle of the ray with respect to the axis OZ, the angle that the normal must have at the point intercepted by the ray of the new curve to send the ray back to the front is calculated.

This method is then reiterated for various values of Y. For the mirror 9 at a frequency of 335 GHz, eight planes (X, Z) were chosen for Y varying from 2 to 9 mm by steps of f 1 mm. Eight curves are then obtained, the polynomial coefficients of which vary with Y and can be once again fitted to obtain the equation of the surface of the mirror 9. For example, all of the calculations and the building of the surface of the mirror 9 can be carried out with the software Maple®.

FIG. 4D shows an example of a file of points determined according to the method explained above in relation to FIG. 4C for a grating having a period L of 0.3 mm.

Thus, the present invention proposes a device allowing to achieve relatively significant power levels ranging from several tens of watts at 100 GHz to one watt at 1 THz while being very compact, not exceeding a length of about fifty mm for a diameter of about twenty mm.

1. A device for producing coherent Smith-Purcell electromagnetic radiation comprising:
an electrically conductive diffraction grating, laterally defined by two electrically conductive outer side walls;
a source for emitting an electron beam and propagating the electron beam above the diffraction grating, the electron beam being configured to interact with the diffraction grating so as to produce coherent Smith-Purcell electromagnetic radiation directed upstream of the diffraction grating in a predetermined direction; and
a mirror configured to collect most of the electromagnetic radiation and to redirect it parallel to the diffraction grating to an exit downstream of the diffraction grating, the mirror including a reflective surface, a geometric shape of which is determined on a basis of a radiation pattern of the diffraction grating defining various modes emitted by the diffraction grating.

2. The device according to claim 1, wherein characteristics of the electron beam include:
a speed of the electrons being sufficiently low so that in a dispersion diagram, in which a frequency is expressed according to a wave number, a straight line representing the frequency of the electron beam according to its wave number and a curve representing, in a first Brillouin zone, dispersion relation in three dimensions corresponding to a fundamental mode of the diffraction grating intersect at a point located outside of an isosceles triangle, a base of which is the same as an axis of the abscissae of the dispersion diagram and one side of which is a line segment having a slope of c/2π passing through an origin of the diagram, where c is the speed of light in a vacuum; and
a current density sufficiently high to excite the fundamental mode of the diffraction grating.

3. The device according to claim 1, comprising:
a tube, an axis of which is parallel to the propagation of the electron beam, the tube being provided with the source on one end and an exit port on the other end, and
a support disposed inside the tube between the source and the exit port and onto which the diffraction grating and the mirror are fastened in a removable manner.

4. The device according to claim 3, wherein the support includes a first part having a circular surface perpendicular to the axis of the tube and provided with a circular orifice to let the electron beam pass through and a second part having a rectangular surface parallel to the axis of the tube, the mirror being fastened onto the first part of the support while the diffraction grating is fastened onto the second part of the support.

5. The device according to claim 4, comprising an element for stopping the beam fastened onto the second part of the support downstream of the diffraction grating, the element for stopping the beam being configured to absorb the beam downstream of the grating.

6. The device according to claim 5, wherein the element for stopping the beam has a geometric shape configured to distribute a current density of the electron beam over a largest possible surface area while letting the electromagnetic radiation pass through the exit port.

7. The device according to claim 3, such that the tube provided with the source and the exit port forms a vacuum chamber inside of which a pressure is approximately 10⁻⁸ mbar to 10⁻⁷ mbar.

8. The device according to claim 1, including elements for focusing and guiding configured to focus, guide and maintain the electron beam in a zone located above the diffraction grating.

9. A method for producing coherent Smith-Purcell electromagnetic radiation comprising:
using an electrically conductive diffraction grating, laterally defined by two electrically conductive outer side walls;
propagating an electron beam above the diffraction grating, the electron beam being configured to interact with the diffraction grating so as to produce coherent Smith-Purcell electromagnetic radiation directed upstream of the diffraction grating in a predetermined direction; and
using a mirror to collect all of the electromagnetic radiation and to redirect it parallel to the diffraction grating to an exit downstream of the diffraction grating, the mirror including a reflective surface, a geometric shape of which is determined on a basis of a radiation pattern of the diffraction grating defining various modes emitted by the diffraction grating.
